(19) United States
(12) Patent Application Publication
(10) Pub. No.: US 2018/0170759 A1
(43) Pub. Date: Jun. 21, 2018

(54) GRAPHENE SYNTHESIS

(71) Applicant: University of Exeter, Exeter Devon (GB)

(72) Inventors: Thomas Hardisty Bointon, Exeter Devon (GB); Matthew D. Barnes, Exeter Devon (GB); Saverio Russo, Exeter Devon (GB); Monica Craciun, Exeter Devon (GB)

(21) Appl. No.: 15/578,953

(22) PCT Filed: Jun. 2, 2016
(86) PCT No.: PCT/GB2016/051614

§ 371 Date: Dec. 1, 2017

(30) Foreign Application Priority Data
Jun. 3, 2015 (GB) 1509570.6

(51) Int. Cl. C01B 32/186; C01B 32/194; C30B 25/18; C30B 29/02; C30B 29/64; G06F 3/044

(52) U.S. Cl. CPC C01B 32/186; C01B 32/194; C30B 25/186; C30B 29/02; G06F 2203/04103; G06F 3/044; C01B 2204/02; G06F 2203/04102; C30B 29/64

(57) ABSTRACT

A method for use in the synthesis of graphene is described that comprises the steps of annealing a substrate in a hydrogen gas atmosphere, subsequently undertaking a deposition and nucleation step in which a relatively thick carbon layer is deposited onto the substrate and subsequently thinned to form small graphene islands or nuclei, undertaking a graphene growth step in which the graphene islands or nuclei expand and coalesce, and subsequently allowing the substrate to cool. A sensor 10 incorporating the graphene sheet is also described.

This invention relates to a method for use in the synthesis of graphene, in particular to a method permitting the synthesis of relatively large dimension graphene sheets, and to sensor device that may be manufactured using graphene sheets synthesised using the method.

A number of methods are known for use in the synthesis of graphene. By way of example, graphene flakes can be produced by exfoliation, for example using an adhesive tape, from a graphite element. However, the flakes produced in this manner are typically of small dimensions. Whilst they may be suitable for use in some applications, and in conducting research in relation to the properties and potential uses of graphene, flakes produced in this manner are often of little use in the commercial production of graphene based devices. Another technique that is employed involves the chemical vapour deposition of monolayer graphene on a copper substrate. This has typically been achieved by using a hot wall CVD system in which the copper substrate, typically in the form of a foil, is heated to a temperature in the region of 1000° C. whilst a precursor hydrocarbon gas flows over and around the substrate. The process is slow, typically involving a processing time in the region of several hours. Consequently, whilst relatively large dimension graphene sheets can be produced, graphene produced in this manner is generally relatively expensive.

One object of the invention is to provide a method for use in the synthesis of graphene in which at least some of the disadvantages with current techniques are overcome or are reduced.

According to a first aspect of the invention there is provided a method for use in the synthesis of graphene comprising the steps of annealing a substrate in a hydrogen gas atmosphere, subsequently undertaking a deposition and nucleation step in which a relatively thick carbon layer is deposited onto the substrate and subsequently thinned to form small graphene islands or nuclei, undertaking a graphene growth step in which the graphene islands or nuclei expand and coalesce, and subsequently allowing the substrate to cool.

The deposition and graphene nucleation step preferably comprises heating the substrate using a resistively heated stage whilst in an atmosphere containing a precursor gas, and the graphene growth step preferably comprises continuing to heat the substrate using the resistively heated stage whilst in an atmosphere containing a higher concentration of the precursor gas

The precursor gas is preferably methane gas.

Conveniently, whilst the annealing step is undertaken, the substrate is heated to a temperature in the region of 1000-1100° C. for a period in the region of 10 minutes. For the graphene nucleation step, the temperature is preferably in the region of 950-1035° C., for example at around 1000° C. The graphene nucleation step preferably has a duration in the region of 40 seconds. During the graphene nucleation step, the flow rate at which methane gas is applied to the substrate is preferably in the range of 1.2 to 1.6 sccm, more preferably about 1.4 sccm. During the graphene growth step, the flow rate is preferably increased to in the region of 6.5-7.5 sccm, more preferably about 7 sccm, the graphene growth step having a duration in the region of 300 seconds.

It will be appreciated that the graphene synthesis method outlined above is of considerably shorter duration than that of the hot wall CVD technique mentioned hereinbefore. As a consequence, graphene sheets can be synthesised rapidly, at an industrial scale, and at relatively low cost.

After synthesis in this manner, the graphene sheet may be transferred from the copper substrate to another substrate, if desired. For example, it may be transferred to a SiO₂/Si or PEN substrate. By way of example, a PMMA coating may be applied to the graphene sheet and, after curing of the PMMA coating, the copper substrate may be etched away. After etching has been completed, the graphene sheet and PMMA coating may be placed into deionised water before being transferred to the SiO₂/Si or PEN substrate.

Prior to transfer from the copper substrate, steps may be undertaken to shape the graphene sheet and/or apply electrical contacts thereto.

According to another aspect of the invention there is provided a graphene based sensor comprising at least one graphene sheet synthesised using the method outlined hereinbefore. By way of example, the sensor may comprise a capacitive touch sensor comprising first and second graphene sheet elements separated by a dielectric material layer. With such an arrangement, upon the sensor being touched, deflection of one of the graphene sheets and the underlying dielectric material results in a localised reduction in the separation of the graphene sheets, and hence in a localised change in the capacitance.

The first graphene sheet element preferably comprises a series of graphene strips arranged parallel to one another, the second graphene sheet element preferably comprising a similar series of graphene strips arranged parallel to one another, the strips of the first element extending substantially perpendicularly to the strips of the second element. By providing each strip with a respective electrical contact, and by appropriate connections to the strips, the location of the point at which the sensor is being touched can be identified.

The invention will further be described, by way of example, with reference to the accompanying drawings, in which:

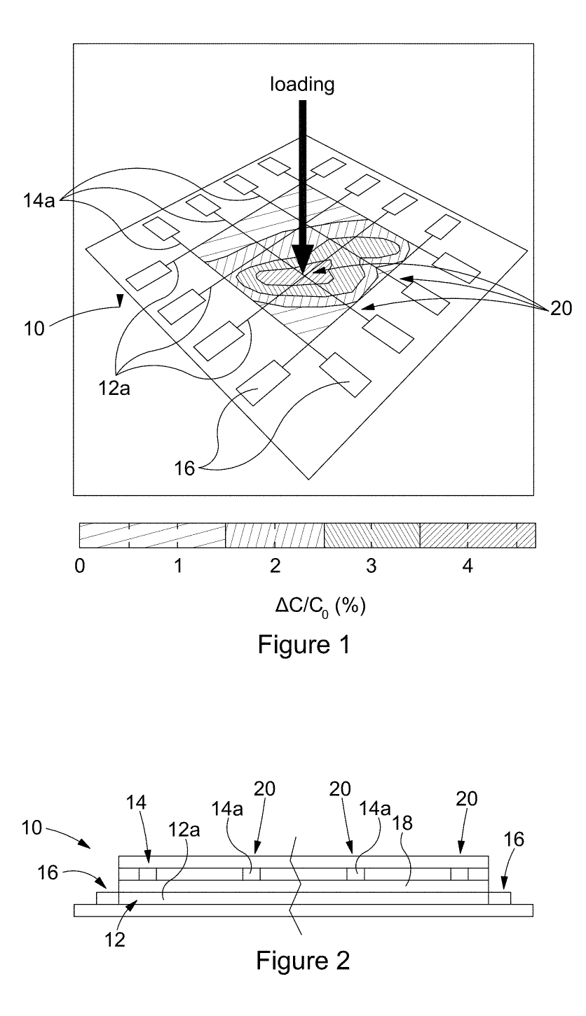

FIG. 1 is a view illustrating a sensor in accordance with an embodiment of the invention;

FIG. 2 is a diagrammatic view illustrating the sensor of FIG. 1;

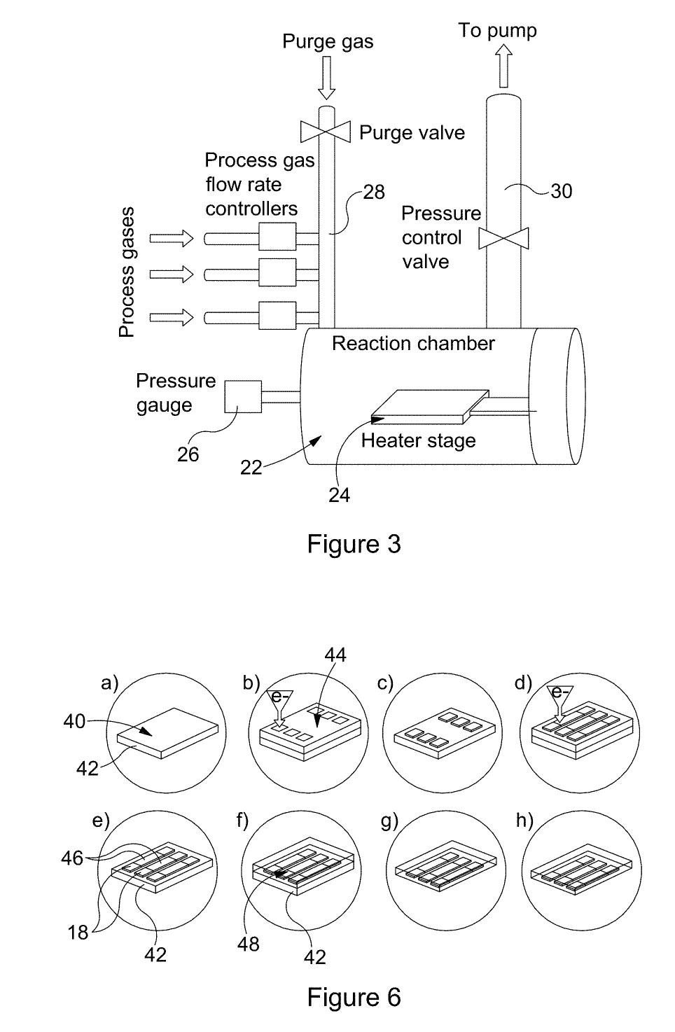

FIG. 3 is a view illustrating an apparatus used in the synthesis of a graphene sheet, for example for use in the sensor of FIG. 1;

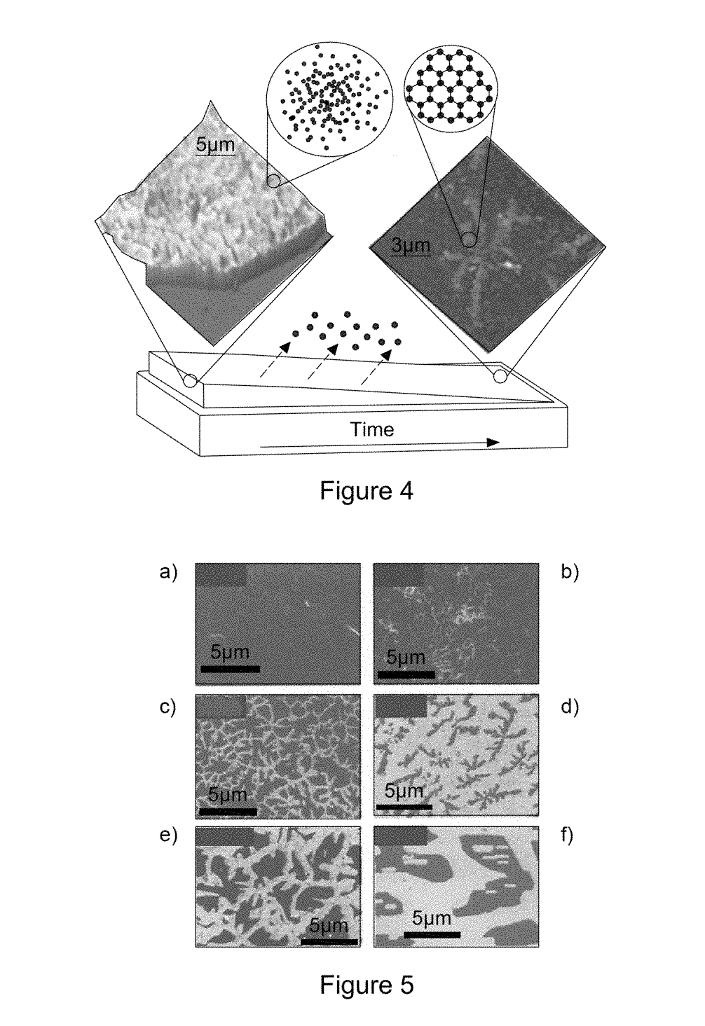

FIG. 4 is an illustration representing the synthesis of the graphene sheet;

FIGS. 5a to 5f are SEM micrographs illustrating the formation of the graphene sheet; and

FIGS. 6a to 6h are views illustrating stages in the formation of the sensor of FIG. 1 from the graphene sheet.

Referring firstly to FIGS. 1 and 2, a sensor 10 is illustrated. The sensor 10 takes the form of a capacitive touch sensor operable to provide an output indicating to which part of the sensor a load has been applied, for example by a user touching a surface of the sensor 10.

The sensor 10 comprises a pair of graphene sheet elements 12, 14, each of which is made up of a series of substantially parallel, elongate strips 12a, 14a, which are spaced apart from one another. Each strip 12a, 14a has an electrical contact 16 electrically connected thereto. The contacts 16 are conveniently of gold form.

The first sheet element 12 is spaced apart from the second element sheet 14 by a layer 18 of a suitable dielectric material, in this case PMMA. The strips 12a of the first element 12 are thus electrically insulated from the strips 14a of the second element 14. As the strips 12a are spaced apart from one another, and the strips 14a are likewise spaced apart from one another, the strips 12a, 14a are electrically insulated from one another.

It will be appreciated that where each strip 12a of the first element 12 aligns with one of the strips 14a of the second element 14, the overlapping strips 12a, 14a and the part of the dielectric material located therebetween together form a series of capacitor regions 20. By electrically connecting an appropriate monitoring device (not shown) to the contacts 16, the capacitance of each of these capacitor regions 20 can be monitored.

In use, when the sensor 10 is at rest with nothing contacting it or bearing against it, the dielectric material layer 18 holds the strips 12a apart from the strips 14a. The capacitance of each capacitor region 20 will be determined, in part, by the distance by which the strips 12a, 14a are spaced apart in that region 20. Where a load is applied to a part of the sensor 10, then the strips 12a, 14a in the region of the sensor 10 to which the load is applied will be pushed closer together, such displacement resulting in temporary deformation of the dielectric material layer 18 therebetween. The reduction in spacing of the strips 12a, 14a in the region at which the load is applied will give rise to a change in the capacitance of the capacitor region or regions 20 at the location at which the load is applied, and this change in capacitance can be detected by the monitoring device, providing an output indicative of the location on the sensor 10 at which the load has been applied.

The sensor 10 is sensitive to the application of very small loads, for example in the region of 35g, and so is sensitive to, for example, the sensor 10 being lightly touched by a user's finger or the like.

The graphene sheets of the first and second sheet elements 12, 14 are conveniently synthesised using a cold wall CVD technique as described below. FIG. 3 illustrates an apparatus suitable for use in the synthesis of the graphene sheets. As illustrated in FIG. 3, the apparatus comprises a reaction chamber 22, for example of steel form. Located within the reaction chamber 22 is a resistively heated support 24. The support 24 is conveniently removable from the chamber 22, when desired, to assist in the positioning of materials thereon, in use. A thermocouple (not shown) is used to allow monitoring of the temperature of the support 24. A pressure gauge 26 monitors the gas pressure within the reaction chamber 22. Gas inlet and outlet lines 28, 30 are provided to allow the controlled introduction and extraction of gases to and from the reaction chamber 22, thereby allowing control over the atmosphere within the reaction chamber 22.

In order to synthesise a graphene sheet, a copper substrate or foil, for example of approximately 25 μm thickness, is positioned upon the support 24, and the support 24 is located within the reaction chamber 22. A purge gas, for example argon, may be applied to the reaction chamber 22.

The support 24 is resistively heated, the temperature thereof being raised to around 1035° C. whilst hydrogen gas is supplied to the reaction chamber at a rate of 0.4 sccm with the pressure within the reaction chamber 22 controlled so as to be approximately 0.01 Torr. The reaction chamber 22 is held under these conditions for approximately 10 minutes. During this time, annealing of the copper substrate or foil occurs, the grain size of the copper material of the substrate increasing.

After completion of the annealing step, a graphene nucleation step is undertaken in which the temperature of the support 24 is reduced to approximately 1000° C. whilst the supply of hydrogen is maintained at the level set out above. In addition, a suitable precursor gas, in this case in the form of methane gas, is supplied to the reaction chamber at a rate of 1.4 sccm, the precursor gas being supplied during this step for a period of approximately 40 seconds. Next, a graphene growth step is undertaken during which the hydrogen supply is maintained and the precursor gas supply rate is increased to 7 sccm for a period of approximately 300 seconds. After completion of the graphene growth step, the precursor gas supply is interrupted and the support 24 allowed to cool to room temperature, the hydrogen supply being maintained during this cooling step.

Once cooled to room temperature, the copper substrate with a graphene sheet synthesised thereon may be removed from the reaction chamber 22.

It will be appreciated that the synthesis of the graphene sheet in this manner is a relatively fast operation compared to the hot wall CVD techniques referred to hereinbefore. Furthermore, as the heating of the substrate is achieved by direct positioning of the substrate upon a resistively heated support, the substrate can be substantially uniformly heated to an accurately control temperature within a controlled environment, minimising the occurrence of chemical reactions that may contaminate the synthesised graphene. During the cooling phase, the substrate and graphene synthesised thereon can be cooled rapidly in a controlled environment, and it has been found that the rapid, controlled cooling can result in the graphene synthesised in this manner being of enhanced quality.

Where graphene is synthesised using a hot wall CVD technique, it is thought that initially two-dimensional islands of graphene form on the substrate. Subsequently, these islands grow to form larger domains which subsequently coalesce to form a continuous sheet. In contrast, synthesis using the method of the invention results, initially, in the formation of a relatively thick carbon material film, for example of thickness in the region of 100 nm, upon the substrate as shown in FIG. 4. During the graphene nucleation step, the layer becomes progressively thinner, evolving into individual islands of graphene material which then, during the growth step expand and coalesce to form the graphene sheet. It is thought that the transition from a relatively thick disordered carbon film adsorbed on the copper substrate to islands of graphene occurs as a consequence of the high temperature, low pressure and presence of the catalytically active surface of the copper substrate. FIGS. 5a to 5f illustrate parts of this process, the dark areas in these drawings representing carbon or graphene material, the lighter areas representing the underlying copper substrate. FIGS. 5a to 5d illustrate the deposition and nucleation step during which thinning of the carbon material layer to form islands of graphene material takes place, and FIGS. 5e and 5f showing the subsequent growth step and coalescing of the islands of graphene material to form larger areas of graphene material. In FIG. 5f, the islands have not yet coalesced sufficiently to form a continuous sheet. However, tests have resulted in the formation of graphene sheets of up to 8 cm² in area.

The product of the method outlined hereinbefore is a graphene sheet 40 synthesised onto a copper substrate 42 or foil as shown in FIG. 6a. In order to form a sensor of the type described hereinbefore, the graphene sheet 40 has a PMMA coating 44 applied thereto, the coating having parts thereof removed, for example by electron beam lithography, at the locations at which the contacts 16 are required. The exposed parts of the graphene sheet 40 are metalised, for example using gold, to form the contacts 18. The PMMA coating is then removed as shown in FIG. 6c. Subsequently, a fresh PMMA coating is applied, and the assembly is etched, for example using electron beam lithography to form an etch mask, and using an argon plasma arrangement to etch the graphene sheet, to form the sheet 40 into individual strips 46 which will form the strips 12a, 14a of the sensor 10. The PMMA coating is replaced with a fresh PMMA coating 48 as shown in FIG. 6g, and the copper substrate is then etched away using, for example iron chloride. The resulting assembly, as shown in FIG. 6h, may then be washed and transferred onto a PEN substrate.

A second graphene sheet formed into strips in the same manner is then positioned over the first graphene sheet, with the strips of the second sheet extending perpendicularly to those of the first sheet, to form the sensor 10.

The sensor fabricated in this manner may be of flexible and transparent form, providing a good level of sensitivity to touch inputs and a fast response time. Fabrication is relatively quick and simple, and so sensors may be fabricated in an economic manner.

It will be appreciated that in the above described method the various etching steps used to shape the graphene sheet to a desired form and the application of the electrical contacts are undertaken prior to the transfer of the graphene sheet from the copper substrate. As a result, the copper substrate can be used to aid handling of the graphene sheet whilst these tasks are undertaken.

Whilst specific temperatures and durations are mentioned hereinbefore in relation to the synthesis of the graphene sheet, it will be appreciated that other temperatures and durations may be used. By way of example, the nucleation and growth steps may be undertaken at a reduced temperature, say at 950° C., with the durations of the nucleation and growth steps being increased, for example to around 6 minutes. Similarly, the temperature may be in the region of 1035° C. with the nucleation and growth steps being of shorter duration.

Whilst the above description relates to a particular method for synthesis of a graphene sheet and to a specific form of sensor using the graphene sheet, it will be appreciated that a wide range of modifications and alterations may be made thereto without departing from the scope of the invention as defined by the appended claims.

1. A method for use in the synthesis of graphene comprising the steps of annealing a substrate in a hydrogen gas atmosphere, subsequently undertaking a deposition and nucleation step in which a relatively thick carbon layer is deposited onto the substrate and subsequently thinned to form small graphene islands or nuclei, undertaking a graphene growth step in which the graphene islands or nuclei expand and coalesce, and subsequently allowing the substrate to cool.

2. A method according to claim 1, wherein the deposition and graphene nucleation step comprises heating the substrate using a resistively heated stage whilst in an atmosphere containing a precursor gas.

3. A method according to claim 2, wherein the graphene growth step comprises heating the substrate using the resistively heated stage whilst in an atmosphere containing a higher concentration of the precursor gas

4. A method according to claim 2, wherein the precursor gas is methane gas.

5. A method according to claim 1, wherein, whilst the annealing step is undertaken, the substrate is heated to a temperature in the region of 1000-1100° C. for a period in the region of 10 minutes.

6. A method according to claim 1, wherein, for the deposition and nucleation step, the substrate temperature is in the region of 950-1035° C.

7. A method according to claim 6, wherein for the deposition and graphene nucleation step the substrate temperature is around 1000° C.

8. A method according to claim 1, wherein the deposition and graphene nucleation step has a duration in the region of 40 seconds.

9. A method according to claim 1, wherein, during the graphene nucleation step, the flow rate at which methane gas is applied to the substrate is in the range of 1.2 to 1.6 sccm.

10. A method according to claim 9, wherein the flow rate during the nucleation step is about 1.4 sccm.

11. A method according to claim 1, wherein during the graphene growth step, the flow rate is in the region of 6.5-7.5 sccm.

12. A method according to claim 11, wherein during the graphene growth step the flow rate is about 7 sccm.

13. A method according to claim 1, wherein the graphene growth step has a duration in the region of 300 seconds.

14. A method according to claim 1, further comprising, whilst the synthesised graphene sheet is located upon the substrate, undertaking steps to shape the graphene sheet and/or apply electrical contacts thereto.

15. A method according to claim 1, further comprising transferring the synthesised graphene sheet from the substrate to a SiO2/Si or PEN substrate.

16. A graphene based sensor comprising at least one graphene sheet synthesised using a method comprising the steps of annealing a substrate in a hydrogen gas atmosphere, subsequently undertaking a deposition and nucleation step in which a relatively thick carbon layer is deposited onto the substrate and subsequently thinned to form small graphene islands or nuclei, undertaking a graphene growth step in which the graphene islands or nuclei expand and coalesce, and subsequently allowing the substrate to cool.

17. A sensor according to claim 16, wherein the sensor comprises a capacitive touch sensor comprising first and second graphene sheet elements separated by a dielectric material layer.

18. A sensor according to claim 17, wherein the first graphene sheet element comprises a series of graphene strips arranged parallel to one another, the second graphene sheet element comprising a similar series of graphene strips arranged parallel to one another, the strips of the first element extending substantially perpendicularly to the strips of the second element.

19. A sensor according to claim 18, wherein each strip is provided with a respective electrical contact.
